(19) United States
(12) Patent Application Publication
(10) Pub. No.: US 2022/0027536 A1
(43) Pub. Date: Jan. 27, 2022

(54) METHOD AND SYSTEM FOR GENERATING TRAINING DATA FOR A MACHINE LEARNING MODEL FOR PREDICTING PERFORMANCE IN ELECTRONIC DESIGN

(71) Applicant: Agency for Science, Technology and Research, Singapore (SG)

(72) Inventors: Rahul Dutta, Singapore (SG); Raju Salahuddin, Singapore (SG); Kevin Tshun Chuan Chai, Singapore (SG)

(21) Appl. No.: 17/296,657

(22) PCT Filed: Nov. 26, 2019
(86) PCT No.: PCT/SG2019/050579

§ 371 Date: May 25, 2021

(30) Foreign Application Priority Data
Nov. 26, 2018 (SG) 10201810572P

(51) Int. Cl. G06F 30/27; G06N 20/00

(52) U.S. Cl. CPC G06F 30/27; G06N 20/00

(57) ABSTRACT

There is provided a method of generating training data for a machine learning model for predicting performance in electronic design using at least one processor, the method including: generating a first set of training data based on a first set of input design parameters and an electronic design automation tool; generating a first covariance information associated with the first set of input design parameters based on the first set of training data; determining a second set of input design parameters based on the first covariance information; and generating a second set of training data based on the second set of input design parameters and the electronic design automation tool. There is also provided a corresponding system for generating training data for a machine learning model for predicting performance in electronic design.

### CROSS-REFERENCE TO RELATED APPLICATION

This application claims the benefit of priority of Singapore Patent Application No. 10201810572P, filed on 26 Nov. 2018, the content of which being hereby incorporated by reference in its entirety for all purposes.

### TECHNICAL FIELD

The present invention generally relates to a method of generating training data for a machine learning model for predicting performance in electronic design, and a system thereof.

### BACKGROUND

Machine learning methodology has made headways into analog and mixed signal circuit design in order to augment and fasten time to market for producing good quality circuits. Generation of training data is typically done by perturbing circuit parameters (input design parameters or input vectors) in order to capture and generalize the design boundaries (a priori) and observing the corresponding response through electronic design automation (EDA) simulators (EDA tools) on various performance targets (output vectors). The goal of machine learning algorithms is to learn the non-linear relationships between inputs and outputs as there are no linear or quadratic relationships (e.g., may be referred to as non-parametric learning) and to accurately predict (infer) the response with respect to an unseen (untrain) input vector during execution. The inference which is conditioned around training data is built on a statistical probability of estimating an output as regression or classification. The learned probability distribution P from training data thus forms the underline mechanism of any machine learning model, where the learning problem is to construct a function f based on pair (x, y) inputs-outputs such that it is minimized for x_{N}, y_{N} training samples, i.e., sum of observed square errors (e.g., see Equation (1) below):

$${\sum }_{i = 1}^{N} {[ {y}_{i} - f ( {x}_{i} ) ]}^{2} \qquad Equation ( 1 )$$

or as a mean squared error representation (e.g., see Equation (2) below), the expectation with respect to probability P measured as regression (mean value of output y) of all functions of x:

E[(y−f(x)²|x] Equation (2)

Equation (2) thus also highlights variance of y given x (e.g., see Equation (3) below), where f(x) can be represented as f(x;D), and D is the dependence off(x) on training data.

(f(x; D)−E[y|x])² Equation (3)

Modeling through machine learning may generate many scenarios where f(x;D) may be an accurate approximation with an optimal predictor of y. It may however also be the case where f(x;D) has quite different dependency using other training data sets and results are far away from regression estimator E[y x], thus the machine learning model may be considered as biased on training dataset. Further, as the dimensionality of inputs increase (typically in circuit design), the problem of bias and variance becomes paramount and complex. Often, generating approximation machine leaning models in these cases require complex state of the art neural networks, deep neural networks, statistical estimation theories and methodologies, such as Bayesian models.

Furthermore, machine modelling may start with a static assumption that the training data completely generalized the ground truth and a predictive statistical thus can be derived from learning input-output pairs. It has been reported that usage of statistical uncertainty is centered around a known probability distribution curve during transistor characterization of process, voltage, temperature, parasitics, and power settings, which is a Gaussian distribution, and also where the characterization tool uses statistical uncertainty to determine if further sampling is required and the areas (input perturbations) in which it might be required. It has also been reported use of semi-automatically generating label through statistical understanding of the ground truth.

Accordingly, various conventional methods of generating training data for machine learning in electronic design have been found to introduce high dimensionality, bias and/or variance within the training data which complicates development of machine learning models, such as issues of over or under fitting, which result in as well as resulting in inefficiencies in the electronic design process, such as higher EDA simulation time and cost.

A need therefore exists to provide a method of generating training data for a machine learning model for predicting performance in electronic design, and a system thereof, that seek to overcome, or at least ameliorate, one or more of the deficiencies in existing methods/systems for generating training data for machine learning in electronic design, such as but not limited to, reducing dimensionality, bias and/or variance within the training data, resulting in improvements in the development of the machine learning model(s) trained based on the training data, such as improved efficiencies and/or effectiveness in the electronic design process. It is against this background that the present invention has been developed.

### SUMMARY

According to a first aspect of the present invention, there is provided a method of generating training data for a machine learning model for predicting performance in electronic design using at least one processor, the method comprising:

generating a first set of training data based on a first set of input design parameters and an electronic design automation tool;

generating a first covariance information associated with the first set of input design parameters based on the first set of training data;

determining a second set of input design parameters based on the first covariance information; and

generating a second set of training data based on the second set of input design parameters and the electronic design automation tool.

According to a second aspect of the present invention, there is provided a system for generating training data for a machine learning model for predicting performance in electronic design, the system comprising:

a memory; and

at least one processor communicatively coupled to the memory and configured to:

generate a first set of training data based on a first set of input design parameters and an electronic design automation tool;

generate a first covariance information associated with the first set of input design parameters based on the first set of training data;

determine a second set of input design parameters based on the first covariance information; and

generate a second set of training data based on the second set of input design parameters and the electronic design automation tool.

According to a third aspect of the present invention, there is provided a computer program product, embodied in one or more non-transitory computer-readable storage mediums, comprising instructions executable by at least one processor to perform a method of generating training data for a machine learning model for predicting performance in electronic design, the method comprising:

generating a first set of training data based on a first set of input design parameters and an electronic design automation tool;

generating a first covariance information associated with the first set of input design parameters based on the first set of training data;

determining a second set of input design parameters based on the first covariance information; and

generating a second set of training data based on the second set of input design parameters and the electronic design automation tool.

### BRIEF DESCRIPTION OF THE DRAWINGS

Embodiments of the present invention will be better understood and readily apparent to one of ordinary skill in the art from the following written description, by way of example only, and in conjunction with the drawings, in which:

FIG. 1 depicts a flow diagram of a method of generating training data for a machine learning model for predicting performance in electronic design, according to various embodiments of the present invention;

FIG. 2 depicts a schematic block diagram of a system for generating training data for a machine learning model for predicting performance in electronic design, according to various embodiments of the present invention;

FIG. 3 depicts a schematic block diagram of an exemplary computer system in which a system for generating training data for a machine learning model for predicting performance in electronic design, according to various embodiments of the present invention, may be realized or implemented;

FIG. 4 illustrates examples of large negative covariance, near zero covariance and large positive covariance, in a sampled input-output pair, according to various example embodiments of the present invention;

FIG. 5 illustrates a case where more data points are needed around the sampled input-output pair, according to various example embodiments of the present invention;

FIG. 6 depicts a schematic overview of a method of generating training data for a machine learning model for predicting performance in electronic design, according to various example embodiments of the present invention;

FIG. 7 depicts an example covariance matrix, plotted amongst various inputs (input design parameters), according to various example embodiments of the present invention;

FIG. 8 depicts an enlarged version of the two-stage operation amplifier circuit, with various input design parameters shown, according to various example embodiments of the present invention;

FIG. 9 depicts another example covariance matrix, plotted against various inputs and outputs, according to various example embodiments of the present invention;

FIG. 10 depicts a two-stage operational amplifier training phase, according to various example embodiments of the present invention;

FIG. 11 depicts an example pseudo code for a method of generating training data for a machine learning model for predicting performance in electronic design, according to various example embodiments of the present invention;

FIG. 12A depicts a plot showing the Training Error and Testing Error at 30% training size which indicates a case of high bias, according to various example embodiments of the present invention;

FIG. 12B depicts a plot showing the Training Error and Testing Error at 30% training size which indicates a case of high variance, according to various example embodiments of the present invention;

FIG. 13A depicts a plot comparing performance of different machine learning models in relation to an operational amplifiers (low complexity design);

FIG. 13B depicts a plot comparing performance of different machine learning models in relation to a DC-DC converter (medium complexity design); and

FIG. 14 depicts a plot comparing the performance accuracy of different types of machine learning models.

### DETAILED DESCRIPTION

Various embodiments of the present invention provide a method of generating training data for a machine learning model for predicting performance in electronic design, and a system thereof.

As described in the background of the present application, various conventional methods of generating training data for machine learning in electronic design have been found to introduce high dimensionality, bias and/or variance within the training data which complicates development of machine learning models, such as issues of over or under fitting, which result in as well as resulting in inefficiencies in the electronic design process, such as higher electronic design automation (EDA) simulation time and cost. Accordingly, various embodiments of the present invention provide a method of generating training data for a machine learning model for predicting performance in electronic design, and a system thereof, that seek to overcome, or at least ameliorate, one or more of the deficiencies in existing methods/systems for generating training data for machine learning in electronic design, such as but not limited to, reducing dimensionality, bias and/or variance within the training data, resulting in improvements in the development of the machine learning model(s) trained based on the training data, such as improved efficiencies and/or effectiveness in the electronic design process.

EDA (which may also be referred to as electronic computer-aided design (ECAD)) is a category of software tools for designing and verifying/analyzing electronic systems, such as integrated circuits and printed circuit boards, and is known in the art. For example, an integrated circuit may have an extremely large number of components (e.g., millions of components or more), therefore, EDA tools are necessary for their design. Over time, EDA tools evolved into interactive programs that perform, for example, integrated circuit layout. For example, various companies created equivalent layout programs for printed circuit boards. These integrated circuit and circuit board layout programs may be front-end tools for schematic capture and simulation, which may be known as Computer-Aided Design (CAD) tools and may be classified as Computer-Aided Engineering (CAE). The term “automation” may refer to the ability for end-users to augment, customize, and drive the capabilities of electronic design and verification tools using a computer program (e.g., a scripting language) and associated support utilities. There are a wide variety of programming languages available, and the most commonly used by far are traditional C and its object-oriented offspring, C++. A gate-level netlist may refer to a circuit representation at the level of individual logic gates, registers, and other simple functions. The gate-level netlist may also specify the connections (wires) between the various gates and functions. A component-level netlist may refer to a circuit representation at the level of individual components. As EDA, as well as EDA tools, are well known in the art, they need not be described in detail herein for clarity and conciseness.

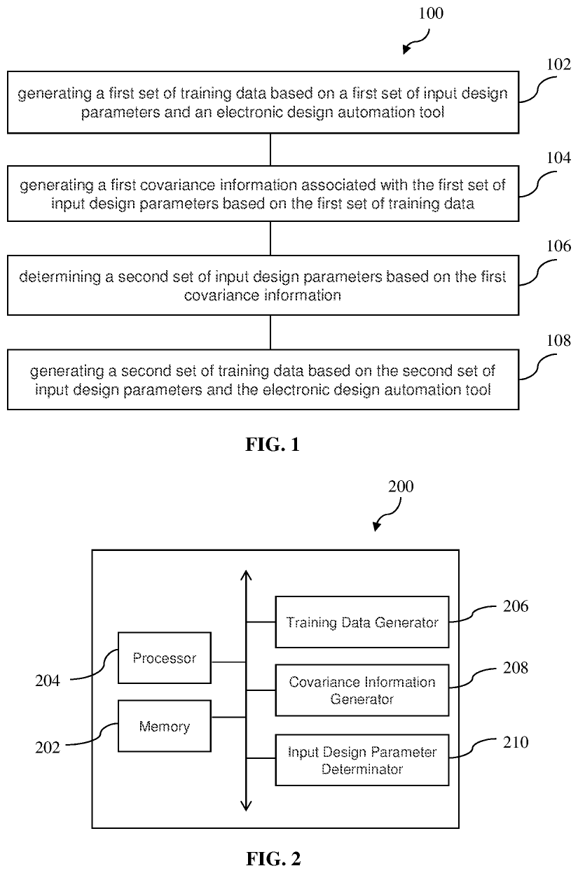

FIG. 1 depicts a flow diagram of a method 100 of generating training data for a machine learning model for predicting performance in electronic design using at least one processor. The method 100 comprises: generating (at 102) a first set of training data based on a first set of input design parameters and an electronic design automation tool; generating (at 104) a first covariance information associated with the first set of input design parameters based on the first set of training data; determining (at 106) a second set of input design parameters based on the first covariance information; and generating (at 108) a second set of training data based on the second set of input design parameters and the electronic design automation tool.

In various embodiments, performance in electronic design may refer to a performance of an electronic system configured based on a set of input design parameters determined in an electronic design of the electronic system. In various embodiments, an electronic system may include an integrated circuit (IC) and/or a printed circuit board (PCB). In various embodiments, the performance of the electronic system may be any measurable electrical property or output of the electronic system, which may be obtained or captured as performance data, such as in the form of a set of performance parameters (e.g., performance metrics). In this regard, it will be appreciated that the performance of the electronic system to be measured or considered may be determined or set as desired or as appropriate, and the present invention is not limited to any particular performance parameters or any particular set of performance parameters.

In various embodiments, the machine learning model may be based on any machine learning model known in the art that is capable of being trained based on training data to output a prediction (or predicted performance data) based on a set of input design parameters (e.g., each input design parameter having a particular or specific parameter value), such as but not limited to, logistic regression, support vector network (SVN), deep neural network (DNN), convolution neural network (CNN), recurrent neural network (RNN), Bayesian neural network or an ensemble of machine learning networks.

In various embodiments, the above-mentioned generating (at 102) a first set of training data comprises: perturbing the first set of input design parameters using the electronic design automation tool to obtain a first set of output performance parameters associated with the first set of input design parameters; and forming first labeled data based on the first set of input design parameters and the first set of output performance parameters.

In various embodiments, the first covariance information comprises a plurality of covariance parameters, each covariance parameter being associated with a respective data pair (e.g., unique data pair) of an input design parameter of the first set of input design parameters and an output performance parameter of the first set of output performance parameter.

In various embodiments, the above-mentioned each covariance parameter is based on a Pearson correlation coefficient associated with the respective data pair.

In various embodiments, the first covariance information is a first covariance matrix comprising the plurality of covariance parameters as elements therein.

In various embodiments, the above-mentioned determining (at 106) a second set of input design parameters comprises selecting (or identifying) each input design parameter of the first set of input design parameters having a parameter value that satisfies a first predetermined threshold condition. In various embodiments, the set of selected (or identified) input design parameters may form the second set of input design parameters. In various other embodiments, a random subset of input design parameters may be obtained from the selected (or identified) set of input design parameters to form the second set of input design parameters. In various embodiments, the first predetermined threshold condition may be an absolute parameter value equal to or greater than a predetermined or predefined value. Accordingly, in various embodiments, the second set of input design parameters may be a subset of the first set of input design parameters.

In various embodiments, the parameter value of the above-mentioned each input design parameter ranges from −1 to 1, and the first predetermined threshold condition is an absolute parameter value of about 0.5 or greater. In various embodiments, the first predetermined threshold condition may be an absolute parameter value of about 0.6 or greater, 0.7 or greater, 0.8 or greater, or 0.9 or greater.

In various embodiments, the above-mentioned generating (at 108) a second set of training data comprises: perturbing the second set of input design parameters using the electronic design automation tool to obtain a second set of output performance parameters associated with the second set of input design parameters; and forming second labeled data based on the second set of input design parameters and the second set of output performance parameters.

In various embodiments, the method 100 is configured to generate the training data iteratively in a plurality of iterations, comprising a first iteration and one or more subsequent iterations. The first iteration comprises: the above-mentioned generating (at 104) a first covariance information associated with the first set of input design parameters based on the first set of training data; the above-mentioned determining (at 106) a second set of input design parameters based on the first covariance information; and the above-mentioned generating (at 108) a second set of training data based on the second set of input design parameters using the electronic design automation tool. In each of the one or more subsequent iterations, the subsequent iteration comprises: generating a further covariance information associated with the set of input design parameters obtained in the immediately previous iteration based on at least the set of training data generated at the immediately previous iteration; determining a further set of input design parameters based on the further convariance information; and generating a further set of training data based on the further set of input design parameters and the electronic design automation tool.

In various embodiments, the method 100 continues from a current iteration to a subsequent iteration of the plurality of iterations until the further covariance information is determined to satisfy a predetermined consistency condition. In various embodiments, the predetermined consistency condition may be the covariance information generated at a predetermined number of consecutive iterations are determined to be within a predetermined variation or deviation. By way of example only and without limtation, the predetermined number of consecutive iterations may be three, four, five, or more. Also by way of example only and without limitation, the predetermined variation may be within about 5%, within about 3%, within about 2%, within about 1% or less.

FIG. 2 depicts a schematic block diagram of a system 200 for generating training data for a machine learning model for predicting performance in electronic design according to various embodiments of the present invention, such as corresponding to the method 100 of generating training data for a machine learning model for predicting performance in electronic design as described hereinbefore according to various embodiments of the present invention. The system 200 comprises a memory 202, and at least one processor 204 communicatively coupled to the memory 202 and configured to: generate a first set of training data based on a first set of input design parameters and an electronic design automation tool; generate a first covariance information associated with the first set of input design parameters based on the first set of training data; determine a second set of input design parameters based on the first covariance information; and generate a second set of training data based on the second set of input design parameters and the electronic design automation tool.

It will be appreciated by a person skilled in the art that the at least one processor 204 may be configured to perform the required functions or operations through set(s) of instructions (e.g., software modules) executable by the at least one processor 204 to perform the required functions or operations. Accordingly, as shown in FIG. 2, the system 20 may comprise a training data generator (or a training data generating module or circuit) 206; a covariance information generator (or a covariance information generating module or circuit) 208; and an input design parameter determinator (or an input design parameter determining module or circuit) 210. The training data generator 206 is configured to generate a first set of training data based on a first set of input design parameters and an electronic design automation tool. The covariance information generator 208 is configured to generate a first covariance information associated with the first set of input design parameters based on the first set of training data. The input design parameter determinator 210 is configured to determine a second set of input design parameters based on the first covariance information. The training data generator 206 is further configured to generate a second set of training data based on the second set of input design parameters and the electronic design automation tool.

It will be appreciated by a person skilled in the art that the above-mentioned modules are not necessarily separate modules, and one or more modules may be realized by or implemented as one functional module (e.g., a circuit or a software program) as desired or as appropriate without deviating from the scope of the present invention. For example, two or more of the training data generator 206, the covariance information generator 208 and the input design parameter determinator 210 may be realized (e.g., compiled together) as one executable software program (e.g., software application or simply referred to as an “app”), which for example may be stored in the memory 202 and executable by the at least one processor 204 to perform the functions/operations as described herein according to various embodiments.

In various embodiments, the system 200 corresponds to the method 100 as described hereinbefore with reference to FIG. 1, therefore, various functions or operations configured to be performed by the least one processor 204 may correspond to various steps of the method 100 described hereinbefore according to various embodiments, and thus need not be repeated with respect to the system 200 for clarity and conciseness. In other words, various embodiments described herein in context of the methods are analogously valid for the respective systems, and vice versa.

For example, in various embodiments, the memory 202 may have stored therein the training data generator 206, the covariance information generator 208 and/or the input design parameter determinator 210, which respectively correspond to various steps of the method 100 as described hereinbefore according to various embodiments, which are executable by the at least one processor 204 to perform the corresponding functions/operations as described herein.

A computing system, a controller, a microcontroller or any other system providing a processing capability may be provided according to various embodiments in the present disclosure. Such a system may be taken to include one or more processors and one or more computer-readable storage mediums. For example, the system 200 described hereinbefore may include a processor (or controller) 204 and a computer-readable storage medium (or memory) 202 which are for example used in various processing carried out therein as described herein. A memory or computer-readable storage medium used in various embodiments may be a volatile memory, for example a DRAM (Dynamic Random Access Memory) or a non-volatile memory, for example a PROM (Programmable Read Only Memory), an EPROM (Erasable PROM), EEPROM (Electrically Erasable PROM), or a flash memory, e.g., a floating gate memory, a charge trapping memory, an MRAM (Magnetoresistive Random Access Memory) or a PCRAM (Phase Change Random Access Memory).

In various embodiments, a “circuit” may be understood as any kind of a logic implementing entity, which may be special purpose circuitry or a processor executing software stored in a memory, firmware, or any combination thereof. Thus, in an embodiment, a “circuit” may be a hard-wired logic circuit or a programmable logic circuit such as a programmable processor, e.g., a microprocessor (e.g., a Complex Instruction Set Computer (CISC) processor or a Reduced Instruction Set Computer (RISC) processor). A “circuit” may also be a processor executing software, e.g., any kind of computer program, e.g., a computer program using a virtual machine code, e.g., Java. Any other kind of implementation of the respective functions which will be described in more detail below may also be understood as a “circuit” in accordance with various alternative embodiments. Similarly, a “module” may be a portion of a system according to various embodiments in the present invention and may encompass a “circuit” as above, or may be understood to be any kind of a logic-implementing entity therefrom.

Some portions of the present disclosure are explicitly or implicitly presented in terms of algorithms and functional or symbolic representations of operations on data within a computer memory. These algorithmic descriptions and functional or symbolic representations are the means used by those skilled in the data processing arts to convey most effectively the substance of their work to others skilled in the art. An algorithm is here, and generally, conceived to be a self-consistent sequence of steps leading to a desired result. The steps are those requiring physical manipulations of physical quantities, such as electrical, magnetic or optical signals capable of being stored, transferred, combined, compared, and otherwise manipulated.

Unless specifically stated otherwise, and as apparent from the following, it will be appreciated that throughout the present specification, discussions utilizing terms such as “generating”, “determining”, “perturbing”, “forming” or the like, refer to the actions and processes of a computer system, or similar electronic device, that manipulates and transforms data represented as physical quantities within the computer system into other data similarly represented as physical quantities within the computer system or other information storage, transmission or display devices.

The present specification also discloses a system (e.g., which may also be embodied as a device or an apparatus), such as the system 200, for performing the operations/functions of the methods described herein. Such a system may be specially constructed for the required purposes, or may comprise a general purpose computer or other device selectively activated or reconfigured by a computer program stored in the computer. The algorithms presented herein are not inherently related to any particular computer or other apparatus. Various general-purpose machines may be used with computer programs in accordance with the teachings herein. Alternatively, the construction of more specialized apparatus to perform the required method steps may be appropriate.

In addition, the present specification also at least implicitly discloses a computer program or software/functional module, in that it would be apparent to the person skilled in the art that the individual steps of the methods described herein may be put into effect by computer code. The computer program is not intended to be limited to any particular programming language and implementation thereof. It will be appreciated that a variety of programming languages and coding thereof may be used to implement the teachings of the disclosure contained herein. Moreover, the computer program is not intended to be limited to any particular control flow. There are many other variants of the computer program, which can use different control flows without departing from the spirit or scope of the invention. It will be appreciated by a person skilled in the art that various modules described herein (e.g., the training data generator 206, the covariance information generator 208 and/or the input design parameter determinator 210) may be software module(s) realized by computer program(s) or set(s) of instructions executable by a computer processor to perform the required functions, or may be hardware module(s) being functional hardware unit(s) designed to perform the required functions. It will also be appreciated that a combination of hardware and software modules may be implemented.

Furthermore, one or more of the steps of a computer program/module or method described herein may be performed in parallel rather than sequentially. Such a computer program may be stored on any computer readable medium. The computer readable medium may include storage devices such as magnetic or optical disks, memory chips, or other storage devices suitable for interfacing with a general purpose computer. The computer program when loaded and executed on such a general-purpose computer effectively results in an apparatus that implements the steps of the methods described herein.

In various embodiments, there is provided a computer program product, embodied in one or more computer-readable storage mediums (non-transitory computer-readable storage medium), comprising instructions (e.g., the training data generator 206, the covariance information generator 208 and/or the input design parameter determinator 210) executable by one or more computer processors to perform a method 100 of generating training data for a machine learning model for predicting performance in electronic design, as described hereinbefore with reference to FIG. 1. Accordingly, various computer programs or modules described herein may be stored in a computer program product receivable by a system therein, such as the system 200 as shown in FIG. 2, for execution by at least one processor 204 of the system 200 to perform the required or desired functions.

The software or functional modules described herein may also be implemented as hardware modules. More particularly, in the hardware sense, a module is a functional hardware unit designed for use with other components or modules. For example, a module may be implemented using discrete electronic components, or it can form a portion of an entire electronic circuit such as an Application Specific Integrated Circuit (ASIC). Numerous other possibilities exist. Those skilled in the art will appreciate that the software or functional module(s) described herein can also be implemented as a combination of hardware and software modules.

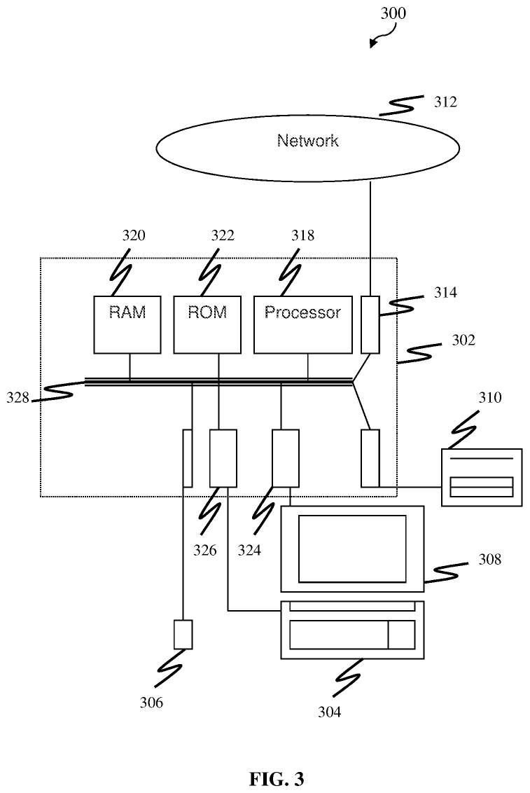

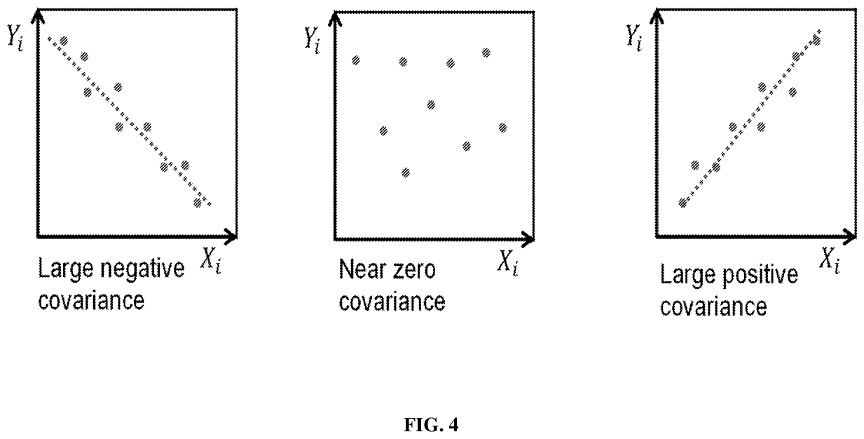

In various embodiments, the system 200 may be realized by any computer system (e.g., desktop or portable computer system) including at least one processor and a memory, such as a computer system 300 as schematically shown in FIG. 3 as an example only and without limitation. Various methods/steps or functional modules (e.g., the training data generator 206, the covariance information generator 208 and/or the input design parameter determinator 210) may be implemented as software, such as a computer program being executed within the computer system 300, and instructing the computer system 300 (in particular, one or more processors therein) to conduct the methods/functions of various embodiments described herein. The computer system 300 may comprise a computer module 302, input modules, such as a keyboard 304 and a mouse 306, and a plurality of output devices such as a display 308, and a printer 310. The computer module 302 may be connected to a computer network 312 via a suitable transceiver device 314, to enable access to e.g., the Internet or other network systems such as Local Area Network (LAN) or Wide Area Network (WAN). The computer module 302 in the example may include a processor 318 for executing various instructions, a Random Access Memory (RANI) 320 and a Read Only Memory (ROM) 322. The computer module 302 may also include a number of Input/Output (I/O) interfaces, for example I/O interface 324 to the display 308, and I/O interface 326 to the keyboard 304. The components of the computer module 302 typically communicate via an interconnected bus 328 and in a manner known to the person skilled in the relevant art.

It will be appreciated by a person skilled in the art that the terminology used herein is for the purpose of describing various embodiments only and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

In order that the present invention may be readily understood and put into practical effect, various example embodiments of the present invention will be described hereinafter by way of examples only and not limitations. It will be appreciated by a person skilled in the art that the present invention may, however, be embodied in various different forms or configurations and should not be construed as limited to the example embodiments set forth hereinafter. Rather, these example embodiments are provided so that this disclosure will be thorough and complete, and will fully convey the scope of the present invention to those skilled in the art.

Various example embodiments provide sampling techniques by using covariance towards machine learning modelling applications of electronic circuits and systems.

Machine learning modelling of analog and mixed signal circuits relies on a large pool of training data in order to accurately approximate. Generation of such training data requires extensive use of EDA tools (simulator) to simulate perturbation of many circuit design parameters (input design parameters). However, this may introduce high dimensionality, bias and variance within training data which may further complicate development of machine learning models. In various example embodiments, a method of generating training data for a machine learning model for predicting performance in electronic design is provided which uses a batch sampling technique to first identify statistical variance of input design parameters to the output performance targets and use this statistical variance information (e.g., covariance information) automatically to generate meaningful perturbations with minimal intervention from circuit designer. The method has been found to drastically reduce the dimension space to be modeled and substantially reduce the complexity of the machine learning model to fit and mitigate issues of, for example, over and under fitting. In various example embodiments, using covariance information automatically to generate meaning perturbations may refer to the use of covariance information to identify the input design parameters where the electronic design is sufficiently or most sensitive, and then drawing (or obtaining) a random sample (a random subset of identified input design parameters) from the set of identified input design parameters and execute the random sample on the EDA simulator in an iterative progressive training loop. As will be described later below, through example experiments conducted, the method has been found to reduce training data size by more than 40% to 60%, with respect to a brute force method.

For better understanding, covariance information will now be described in further detail below, by way of an example only and without limitation, according to various example embodiments of the present invention.

Suppose the input and output of the machine learning model is identified as X and Y, respectively. The covariance r (e.g., Pearson correlation coefficient (PCC)) for a sampled input-output pair (X,Y) with n data sample pairs {(x₁,y₁) . . . (xₙ,yₙ)} may be represented as:

$${r}_{x y} = \frac{\sum {x}_{i} {y}_{i} - n \overline{x} \overline{y}}{( n - 1 ) {s}_{x} {s}_{y}} \qquad Equation ( 4 )$$

where

$$\overline{x} = \frac{1}{n} {\sum }_{i - 1}^{n} {x}_{i}$$

is the mean of individual sample set, analogous for y̅, a dimensionless signed standard deviation score s_{x|y} may be expressed in the form:

$${s}_{x} = \sqrt{\frac{1}{n - 1} {\sum }_{i = 1}^{n} {( {x}_{i -} \overline{x} )}^{2}} \qquad Equation ( 5 )$$

defined for each input feature and output target. For example, it can be observed that (xᵢ−x̅)(yᵢ−y̅) is positive only if xᵢ and yᵢ lie on the same side of their respective mean value, else for vice-versa is negative. Accordingly, as illustrated in FIG. 4, larger absolute value on either side can be identified as strong positive or strong negative correlation.

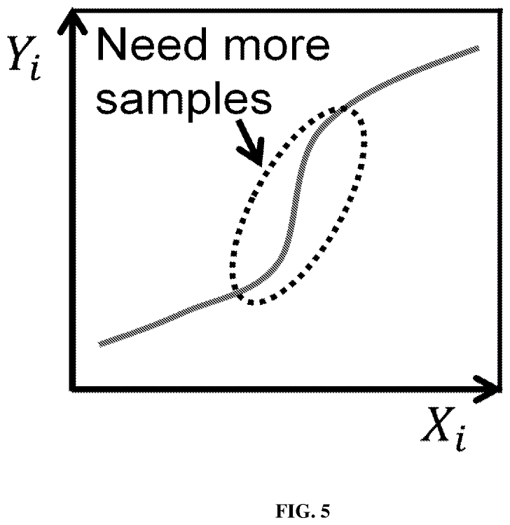

According to various example embodiments, when generating training data for a machine learning model, the value of covariance r_{xy} (value of covariance parameter) guides the sampling of input-output pair. In various example embodiments, if the value of the covariance parameter associated with a sampled input-output pair is large, it may be determined that more data points is needed around that sampled input-output pair to capture the behaviour, such as illustrted in FIG. 5. On the other hand, if the value of the covariance parameter associated with a sampled input-output pair is near zero, it may be determined that less data points is needed for machine learning. In various example embodiments, the covariance information may be in the form of a covariance matrix (or statistical covariance matrix) comprising a plurality of covariance parameters (e.g., an array of covariance parameters) as elements. Accordingly, according to various example embodiments, covariance matrix may be used to identify the most important input design parameters on which the electronic design is sensitive towards.

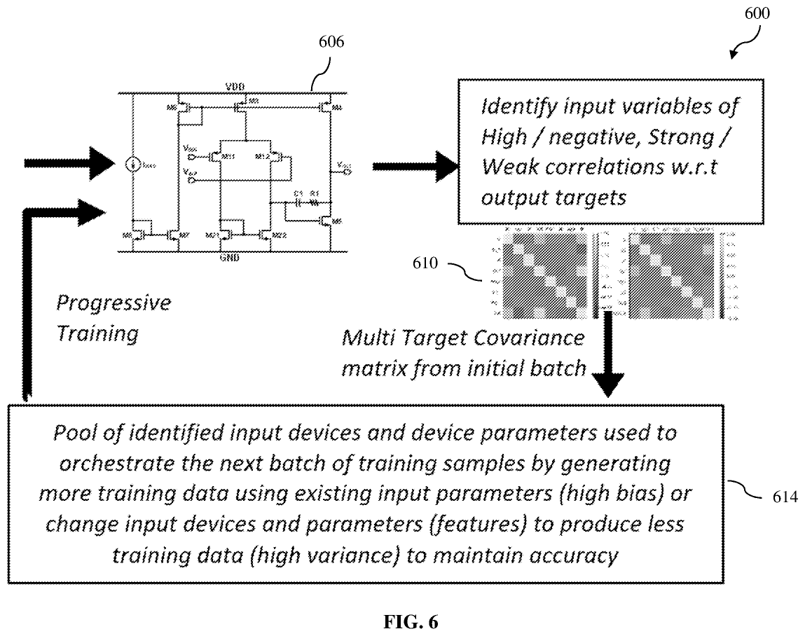

FIG. 6 depicts a schematic overview of a method 600 of generating training data for a machine learning model for predicting performance in electronic design, according to various example embodiments of the present invention. The method 600 may also be referred to as progressive training or learning. As shown in FIG. 6, the method 600 includes, at a first or initial phase, generating a first or initial set of training data based on a first or initial set of input design parameters and an EDA tool, with respect to a circuit 606. By way of an example only and without limitation, FIG. 6 shows the circuit 606 being a two-stage operational amplifier. As shown in FIG. 6, the method 600 further includes generating a first covariance information 610 associated with the first set of input design parameters based on the first set of training data; determining a second set of input design parameters 614 based on the first covariance information 610; and generating a second set of training data based on the second set of input design parameters and the EDA tool, with respect to the circuit 606.

Accordingly, the method 600 may use an initial set (e.g., batch) of training data by randomly perturbing tuning knobs (input design parameters) to get insight into, possible bias and variance behavior of the underline mixed signal circuit. For example, an initial set (e.g., batch) of training data may be obtained by perturbing an initial set of input design parameters determined or selected by circuit designers based on circuit design knowledge. For example, the input parameters may be perturbed in strict ranges to first understand the circuit design topology and the underline CMOS technology. This initial generalization highlights which tune knobs (input design parameters) may be suitable or necessary to be selected and by how much the tuning knobs need to be perturbed (bounded by technology parameters). For example, electronic circuit designs are based on theoretical design knowledge and may be realized using active and passive devices, such as transistors, resistors, capacitors, and so on, together with biasing voltage and current. For example, in the example of an two-stage operational amplifier, the first stage CMOS transistor widths are theoretically known to be contributing to one of the output performance targets of bandwidth. As a result, such an input design parameter may be tuned and perturbed to understand (obtain information on) the circuit bandwidth response. Furthermore, theoretically, there are ratios of CMOS transistors width/length which need to be followed while implementing different stages of an analog circuit, thus to meet output specifications, step size may be determined to run design of experiments to understand the circuit's response. The method 600 uses covariance information, such as in the form of covariance matrix 610 as shown in FIG. 6, and is leveraged together with automatic knob tuning to progressively understand (obtain information on) bias and variance in order to obtain good quality training data with much less samples (sampled input-output pairs).

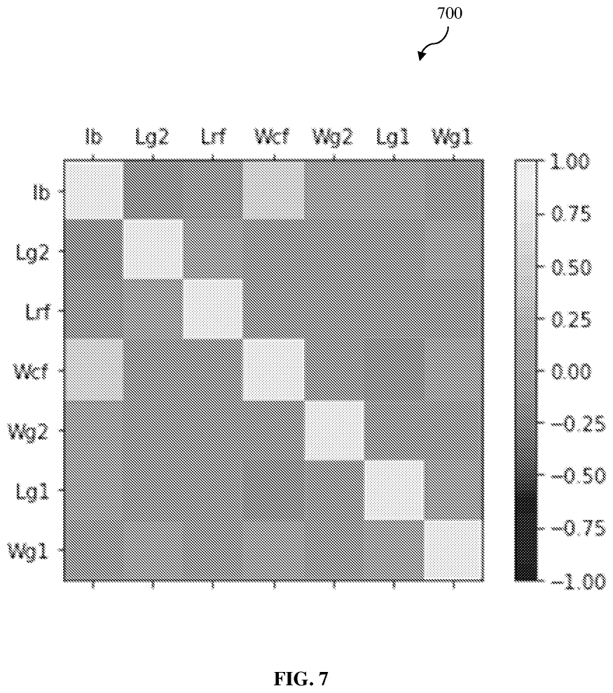

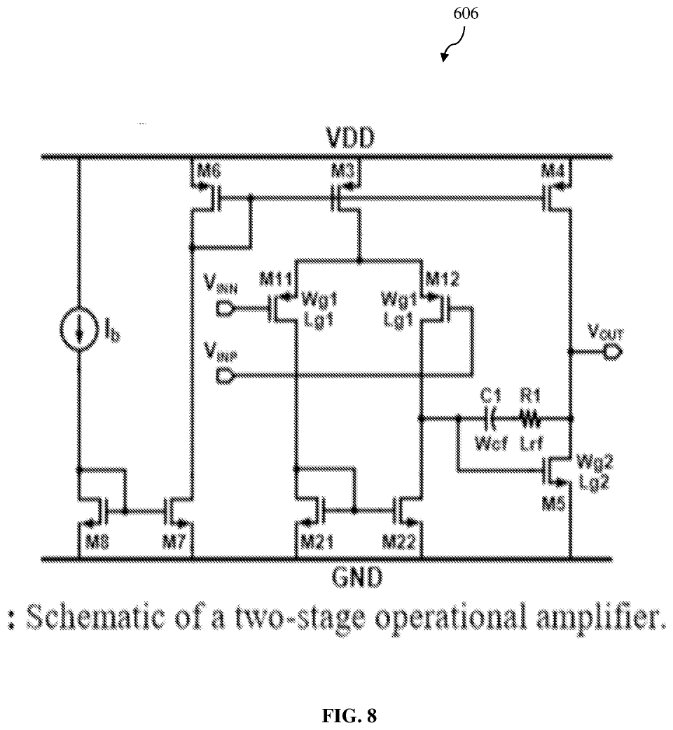

FIG. 7 depicts an example covariance matrix 700, plotted amongst various inputs (input design parameters), according to various example embodiments of the present invention, which is formed based on an initial set of training data generated using an EDA simulator with respect to the two-stage operation amplifier circuit 606 shown in FIG. 6. In FIG. 7, the covariance matrix 700 is a two-dimensional (2D) matrix and is plotted against various inputs to show inter-inputs correlation. FIG. 8 depicts an enlarged version of the two-stage operation amplifier circuit 606, with various input design parameters shown. The covariance matrix 700 is based on bivariate Pearson correlation coefficients (PCC) and highlights the correlation between example features being highly positively or negatively correlated (e.g., on a scale of +1/−1). For example, from the covariance matrix 700 shown in FIG. 7, it can be seen that the bias current (IB) is highly positively correlated to output stage capacitor width (Wcf) and the Length of first stage transistors (Lg1) is weakly negatively correlated to Wcf.

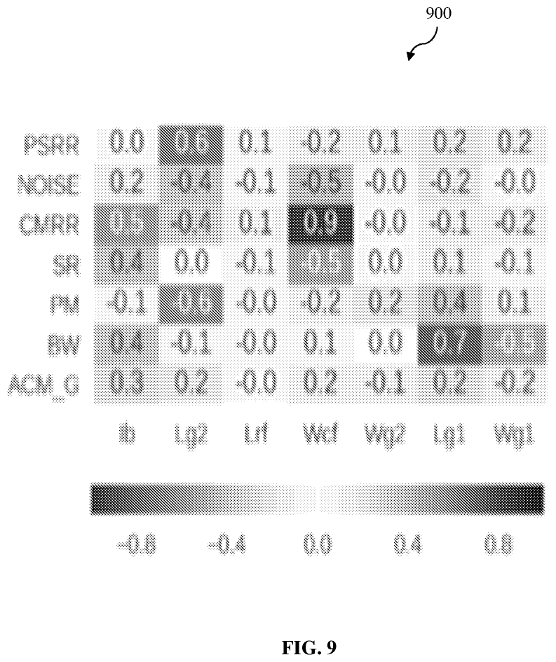

FIG. 9 depicts another example covariance matrix 900, plotted against various inputs (X-axis) (input design parameters) and outputs (Y-axis) (output performance parameters), according to various example embodiments of the present invention, which is formed based on an initial set of training data generated using an EDA simulator with respect to the two-stage operation amplifier circuit 606 shown in FIG. 8. In FIG. 9, the covariance matrix 900 is a 2D matrix and is plotted against various inputs and outputs to show inputs-outputs correlations. As shown in FIG. 9, the inputs (X) includes second stage transistor length and width (Lg2, Wg2), load capacitor width (Wcf), load resistor length (Lrf), first stage transistor length and width (Lg1, Wg1), bias current (Ib), and the outputs (Y) includes gain (ACM_G), phase margin (PM) common mode rejection ratio (CMRR) and bandwidth (BW), noise (NOISE), signal to noise ratio (SR), power supply rejection ratio (PSRR). In particular, the covariance matrix 900 is based upon bivariate Pearson correlation coefficients and plots the 2D matrix using a dimensionless signed score between +1 (denoting highly positively correlated) and −1 (denoting highly negatively correlated), amongst input-output variables.

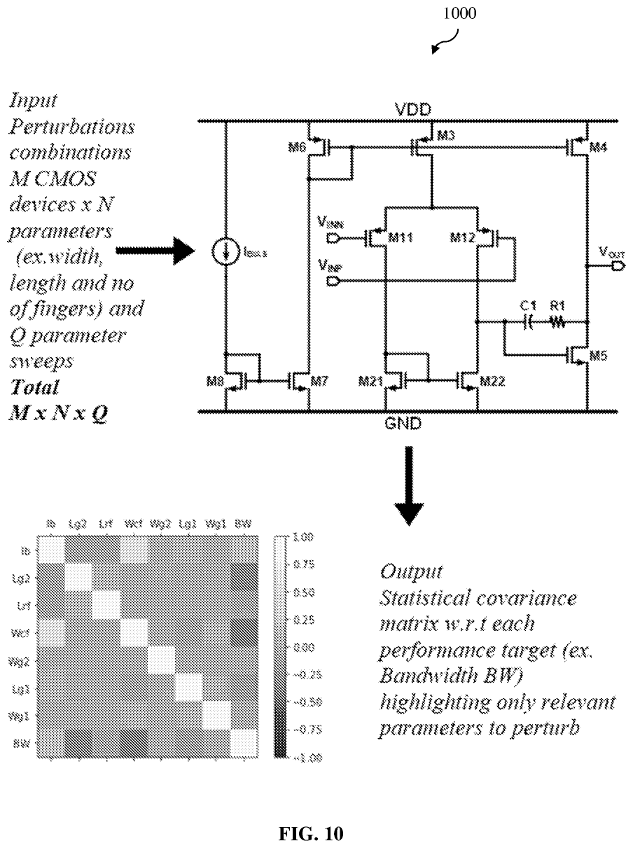

FIG. 10 depicts a two-stage operational amplifier training phase 600 according to various example embodiments of the present invention. Various example embodiments realize the use of statistical information (covariance information, such as covariance matrix) to identify a subset of input design parameters to tweak (perturb), based on the bias and variance sensitivity of the underline circuits. In various example embodiments, since each covariance parameter scores on a scale of +1 and −1 with 0 being a median (very low correlation), any value about +0.5 or above and about −0.5 or below (very high correlation) may be treated as the only suitable or important variables to perturb next, thus reducing dimensionality and perturbation space. By this process, less dimensionality being introduced during the training phase can be achieved. In the two-stage operational amplifier training phase shown in FIG. 10, the total input perturbations of all possible design space is M×N, and an initial batch sample is taken by randomly perturbing, highlighting, highly positive and negative design variable combinations affecting output bandwidth performance target. In particular, Lg2, Wcf, Lg1, Ib are individual input design parameters directly contributing to bandwidth. In this example, pair wise highly positively/negatively correlated are Ib-Wcf, Ib-Lg1 and Lg1-Lg2, Lg1-Wcf, IB-Wg1.

In various example embodiments, a covariance matrix may be generated for each output performance parameter in a set of output performance parameter (e.g., a covariance matrix generated with respect to multiple inputs and one output, such as shown in FIG. 10, whereby the output performance parameter is bandwidth). In various example embodiments, a covariance matrix may be generated with respect to multiple inputs and multiple outputs, such as shown in FIG. 9, where the covariance matrix scores correlation amongst various inputs and outputs.

In various example embodiments, initial training data (e.g., through random perturbations by a circuit designer using theoretical design knowledge) may represent all circuit devices (e.g., active devices, such as transistors and passive devices, such as resistors and capacitors) and all bias conditions, such as voltage and supply current. For each device, there may be multiple parameters (knobs) to tune (e.g., transistor and passive widths and lengths). A subset of input design parameters may be formulated based on the covariance matrix where higher positive or negative scores (values) may identify suitable or essential devices and their parameter correlation to output targets. In this regard, highly positive or negatively correlated parameters (e.g., score about 0.5 or above, or about −0.5 or below, that is, an absolute value greater about 0.5 or greater) correspond to the case of high variance. Furthermore, near zero positive or negative correlated parameters imply the case of high bias. As every iteration attempts to reduce the number of input design parameters in the set of input design parameters, this sampling technique according to various example embodiments reduces the shear permutation and combinations needed to exercise to generate high quality of training data. In various example embodiments, high quality of training data may refer to a sampled data set which captures the circuit response towards high bias and high variance.

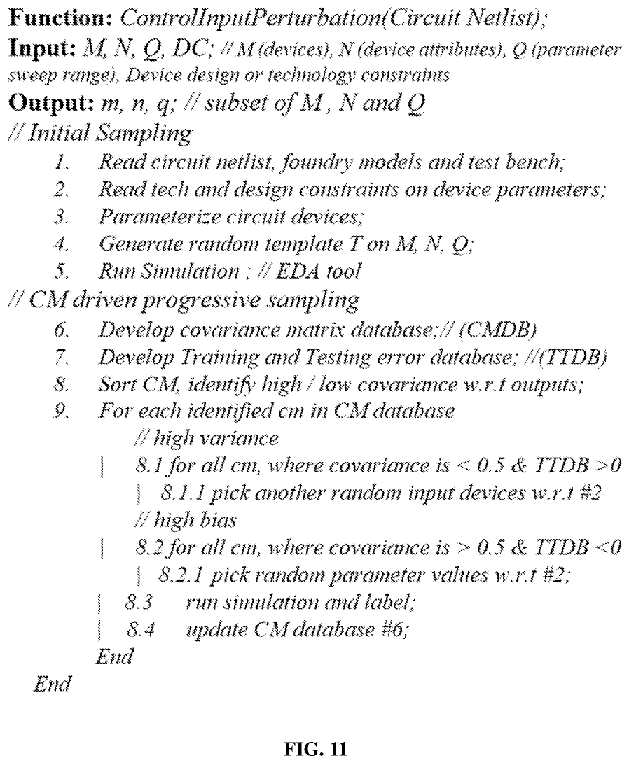

In various example embodiments, training data generation may be guided by iterative and progressive, bias and variation guided feedback to control input perturbations. In various example embodiments, the training data generation may be performed in an iterative loop whereby the stopping criterionis less than 5% variance observed between three successive iterations. In various example embodiments, the feedback may be a software routine (algorithm) which uses technology constraints and/or constraints set by circuit designer to limit design space combinations. By way of an example only and without limitation, an example pseudo code for a method of generating training data for a machine learning model for predicting performance in electronic design, shown in FIG. 11.

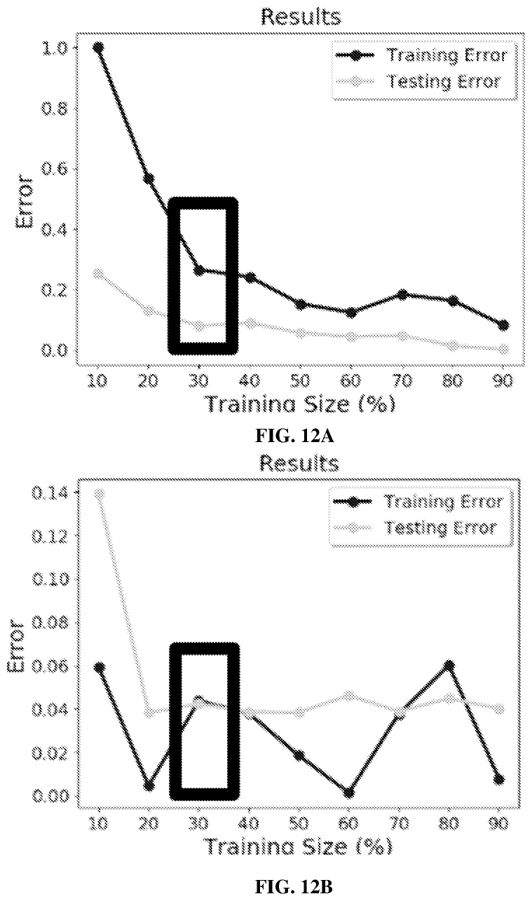

As the covariance matrix database builds progressively, it can be observed if the training data is becoming biased by the training set or achieving good variance (e.g., see FIGS. 12A and 12B) from an initial machine learning model. FIG. 12A shows the Training Error and Testing Error at 30% training size suggest a case of high bias, where the training error decreases with decreasing testing error suggesting even larger training samples for same identified input parameters may increase model accuracy. FIG. 12B shows the Training Error and Testing Error at 30% training size suggest a case of high variance, where training error increases for same testing error for the identified input parameters suggesting larger features of different input combinations may increase model accuracy. In particular, FIGS. 12A and 12B show observation through machine learning modelling, where 30% of training data generated through the method according to various example embodiments shows far less training error, suggesting good quality machine learning modelling. If the circuit has inherent higher bias the train and test errors progressively reduces (FIG. 12A), however if the circuit has inherent high variance the test errors almost stabilize suggesting no further modelling accuracy can be achieved irrespective of the volume of data (FIG. 12B).

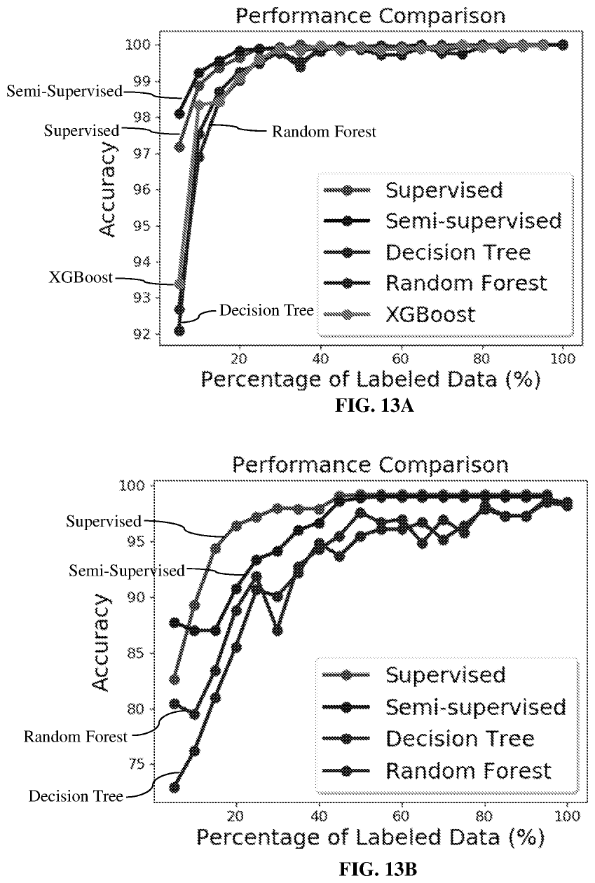

FIG. 13A depicts a plot comparing performance of different machine learning models in relation to an operational amplifiers (low complexity design). In this example experiment, the initial batch of training data generation uses 39 input variables to tweak or perturb with N sweeps, that is, design input parameters include 13 devices×3 attributes. Based on the progressive batch of training data generation using covariance matrix feedback according to various example embodiments, the number of input variables used was advantageously reduced to 21 input variables to tweak or perturb with N sweeps. In this experiment, it was found that 46% less training data was achieved. FIG. 13A depicts downstream machine modelling validation using various supervised and unsupervised algorithms, to show accuracy is almost near 100% suggesting higher quality of training data.

FIG. 13B depicts a plot comparing performance of different machine learning models in relation to a DC-DC converter (medium complexity design). In this example experiment, the initial batch of training data generation uses 75 input variables to tweak or perturb with N sweeps, that is, design input parameters include 25 devices x 3 attributes. Based on the progressive batch of training data generation using covariance matrix feedback according to various example embodiments, the number of input variables used was advantageously reduced to 8 input variables to tweak or perturb with N sweeps. In this experiment, it was found that 68% less training data was achieved.

Conventional methods of training data generation for modeling electronic designs uses designer's knowledge to intelligently produce sampled and labeled data, as a ground truth and to be modeled by state of the art machine/deep learning algorithms. In contrast, the method of training data generation according to various example embodiments drastically changes this conventional methodology and completely relies on automatic statistical methods to first identify sensitive input devices and further augments the training phase with permutations (such as shown in FIG. 6 described hereinbefore) which are meaningful with respect to bias and variance of training data set.

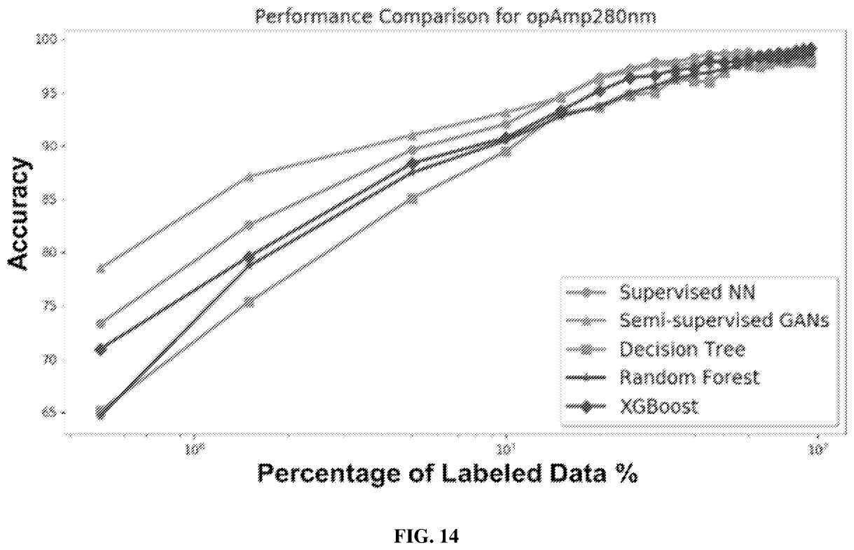

For illustration purpose, experiments with operational amplifiers and DC-DC converters were conducted according to various example embodiments of the present invention. The experiments demonstrated a reduction of 46% and 68% correspondingly on input devices to perturb to produce good quality training dataset. This simplifies the machine models and produces high accuracy probability based models, as shown in FIG. 14. In particular, FIG. 14 depicts a plot comparing the performance accuracy of different types of machine learning models. FIG. 14 shows that the semi-supervised deep learning model was implemented based on the reduced input devices guided by covariance matrix has achieved very high accuracy as compared to supervised, decision trees, random forest and XGBoost algorithms.

Accordingly, the method of generating training data for a machine learning model for predicting performance in electronic design according to various example embodiments of the present invention represents a significant step in adoption of machine learning in electronic design space where EDA tool cost and simulation run times are huge. Reducing training dataset and automatically identifying device perturbations, reduces human intervention and use or prior knowledge in crafting ground truth before modeling can be performed. For example, the corresponding system can run as in a batch mode, in cloud server farms, on a library of mixed signal circuits to generate various forms of training data based on specific EDA simulators or optimizers. Further, the method can be cross adopted to any system which needed to be modeled by machine learning and always relies on human knowledge to make meaningful training data. State of the art machine learning techniques can also be included to guide the proposed algorithm such as reinforcement learning or active learning which can orchester input sample generation based on reward systems as each EDA simulation is time and cost intensive.

Accordingly, the method of generating training data for a machine learning model for predicting performance in electronic design according to various example embodiments of the present invention, has the following advantages:
better training data with less training samples;
simplified machine learning models;
less usage of EDA algorithmic solvers to generate training data;
reduces designers knowledge for feature engineering by use of covariance parameters;
performed as a pre-processing step before a machine learning model can be developed;
automatic training sample generation without human intervention for generating and labeling data to be modeled with machine learning no human engineer involved in the training phase;
training can happen in background i.e. in cloud, progressive training;
methodology to do guide and trade-off for issues with high bias and high variance during machine model development enables to switch between more training samples for less features or more features less training samples;
statistically driven feedback which utilizes batch wise covariance information (small training set size) in order to generate (high dimensional) ground truth data to develop ML models;
reduces the size of training data generation by more than 40% to achieve very high, greater than 96% accuracy.

The method of generating training data for a machine learning model for predicting performance in electronic design according to various example embodiments of the present invention, has also found to have increased performances, including:
about 46 to 68% less training data with respect to the brute force method;
Less training data and high model accuracy saves costs in terms of EDA license tool cost, computer resource cost and engineering time cost, ML model development cost;
For large scale circuits, batch sampling and further sampling guidance with covariance will reduce overhead for manual feature engineering there by simplifying machine models

The method of generating training data for a machine learning model for predicting performance in electronic design according to various example embodiments of the present invention, is also applicable to multiple domains and not just limited to electronic circuit design. The covariance information can be particularly used in modeling any system which uses time series solvers and uses solvers to generate training and testing dataset.

Accordingly, the method of generating training data for a machine learning model for predicting performance in electronic design according to various example embodiments of the present invention, advantageously utilizes statistical data, e.g., the covariance, from a batch of initial training samples to orchestrate sampling for generating training data for electronic circuits and systems; and progressive automatic high quality training data by generating new features or by generating more test data for a fixed set of features are formulated by utilizing covariance which can then be modelled by machine learning easily and accurately.

While embodiments of the invention have been particularly shown and described with reference to specific embodiments, it should be understood by those skilled in the art that various changes in form and detail may be made therein without departing from the scope of the invention as defined by the appended claims. The scope of the invention is thus indicated by the appended claims and all changes which come within the meaning and range of equivalency of the claims are therefore intended to be embraced.

What is claimed is:

1. A method of generating training data for a machine learning model for predicting performance in electronic design using at least one processor, the method comprising:
generating a first set of training data based on a first set of input design parameters and an electronic design automation tool;
generating a first covariance information associated with the first set of input design parameters based on the first set of training data;
determining a second set of input design parameters based on the first covariance information; and
generating a second set of training data based on the second set of input design parameters and the electronic design automation tool.

2. The method according to claim 1, wherein said generating a first set of training data comprises:
perturbing the first set of input design parameters using the electronic design automation tool to obtain a first set of output performance parameters associated with the first set of input design parameters; and
forming first labeled data based on the first set of input design parameters and the first set of output performance parameters.

3. The method according to claim 2, wherein the first covariance information comprises a plurality of covariance parameters, each covariance parameter being associated with a respective data pair of an input design parameter of the first set of input design parameters and an output performance parameter of the first set of output performance parameter.

4. The method according to claim 3, wherein said each covariance parameter is based on a Pearson correlation coefficient associated with the respective data pair.

5. The method according to claim 3, wherein the first covariance information is a first covariance matrix comprising the plurality of covariance parameters as elements therein.

6. The method according to claim 3, wherein said determining a second set of input design parameters comprises selecting each input design parameter of the first set of input design parameters having a parameter value that satisfies a first predetermined threshold condition.

7. The method according to claim 6, wherein the parameter value of said each input design parameter ranges from −1 to 1, and the first predetermined threshold condition is an absolute parameter value of about 0.5 or greater.

8. The method according to claim 6, wherein said generating a second set of training data comprises:
perturbing the second set of input design parameters using the electronic design automation tool to obtain a second set of output performance parameters associated with the second set of input design parameters; and
forming second labeled data based on the second set of input design parameters and the second set of output performance parameters.

9. The method according to claim 1, configured to generate the training data iteratively in a plurality of iterations, comprising a first iteration and one or more subsequent iterations,
wherein the first iteration comprises:
said generating a first covariance information associated with the first set of input design parameters based on the first set of training data;
said determining a second set of input design parameters based on the first covariance information; and
said generating a second set of training data based on the second set of input design parameters using the electronic design automation tool, and
wherein in each of the one or more subsequent iterations, the subsequent iteration comprises:
generating a further covariance information associated with the set of input design parameters obtained in the immediately previous iteration based on at least the set of training data generated at the immediately previous iteration;
determining a further set of input design parameters based on the further convariance information; and
generating a further set of training data based on the further set of input design parameters and the electronic design automation tool.

10. The method according to claim 9, wherein the method continues from a current iteration to a subsequent iteration of the plurality of iterations until the further covariance information is determined to satisfy a predetermined consistency condition.

11. A system for generating training data for a machine learning model for predicting performance in electronic design, the system comprising:
a memory; and
at least one processor communicatively coupled to the memory and configured to:
generate a first set of training data based on a first set of input design parameters and an electronic design automation tool;
generate a first covariance information associated with the first set of input design parameters based on the first set of training data;
determine a second set of input design parameters based on the first covariance information; and
generate a second set of training data based on the second set of input design parameters and the electronic design automation tool.

12. The system according to claim 11, wherein said generate a first set of training data comprises:
perturbing the first set of input design parameters using the electronic design automation tool to obtain a first set of output performance parameters associated with the first set of input design parameters; and
forming first labeled data based on the first set of input design parameters and the first set of output performance parameters.

13. The system according to claim 12, wherein the first covariance information comprises a plurality of covariance parameters, each covariance parameter being associated with a respective data pair of an input design parameter of the first set of input design parameters and an output performance parameter of the first set of output performance parameter.

14. The system according to claim 13, wherein said each covariance parameter is based on a Pearson correlation coefficient associated with the respective data pair.

15. The system according to claim 13, wherein the first covariance information is a first covariance matrix comprising the plurality of covariance parameters as elements therein.

16. The system according to claim 13, wherein said determine a second set of input design parameters comprises selecting each input design parameter of the first set of input design parameters having a parameter value that satisfies a first predetermined threshold condition.

17. The system according to claim 16, wherein the parameter value of said each input design parameter ranges from −1 to 1, and the first predetermined threshold condition is an absolute parameter value of about 0.5 or greater.

18. The system according to claim 16, wherein said generate a second set of training data comprises:
perturbing the second set of input design parameters using the electronic design automation tool to obtain a second set of output performance parameters associated with the second set of input design parameters; and
forming second labeled data based on the second set of input design parameters and the second set of output performance parameters.

19. The system according to claim 11, wherein the at least one processor is configured to generate the training data iteratively in a plurality of iterations, comprising a first iteration and one or more subsequent iterations,
wherein the first iteration comprises:
said generate a first covariance information associated with the first set of input design parameters based on the first set of training data;
said determine a second set of input design parameters based on the first covariance information; and
said generate a second set of training data based on the second set of input design parameters using the electronic design automation tool, and
wherein in each of the one or more subsequent iterations, the subsequent iteration comprises:
generate a further covariance information associated with the set of input design parameters obtained in the immediately previous iteration based on at least the set of training data generated at the immediately previous iteration;
determine a further set of input design parameters based on the further convariance information; and
generate a further set of training data based on the further set of input design parameters and the electronic design automation tool.

20. A computer program product, embodied in one or more non-transitory computer-readable storage mediums, comprising instructions executable by at least one processor to perform a method of generating training data for a machine learning model for predicting performance in electronic design, the method comprising:
generating a first set of training data based on a first set of input design parameters and an electronic design automation tool;
generating a first covariance information associated with the first set of input design parameters based on the first set of training data;
determining a second set of input design parameters based on the first covariance information; and
generating a second set of training data based on the second set of input design parameters and the electronic design automation tool.
